(19) United States
(12) Patent Application Publication
(10) Pub. No.: US 2007/0075717 A1
(43) Pub. Date: Apr. 5, 2007

(54) Lateral interposer contact design and probe card assembly

(75) Inventors: David Kinghorn, Walnut, CA (US); Raffi Garabedian, Monrovia, CA (US); Richard Yabuki, Garden Grove, CA (US); Salleh Ismail, El Monte, CA (US)

Correspondence Address: PILLSBURY WINTHROP SHAW PITTMAN LLP, P.O BOX 10500, McLean, VA, 22102, US

(73) Assignee: TOUCHDOWN TECHNOLOGIES, INC., Baldwin Park, CA (US)

(21) Appl. No.: 11/633,324

(22) Filed: Dec. 4, 2006

Related U.S. Application Data
(63) Continuation-in-part of application No. 11/226,568, filed on Sep. 14, 2005.

(51) Int. Cl. G01R 31/02

(52) U.S. Cl. 324/754

(57) ABSTRACT

The present invention is directed to an interposer having an interposer substrate with an upper surface and a lower surface and at least one resilient contact element having an upper portion and a lower portion. The upper portion extends in a substantially vertical fashion above the upper surface of said interposer substrate, and the lower portion extends in a substantially vertical fashion below the lower surface of said interposer substrate. The upper and lower portions of the resilient contact element are substantially resilient in a direction parallel to the substrate.

### RELATED APPLICATIONS

This application is a continuation-in-part of U.S. patent application Ser. No. 11/226568, filed Sep. 14, 2005, titled “Lateral Interposer Contact Design and Probe Card Assembly,” the disclosure of which is incorporated herein by reference.

### BACKGROUND

The present invention relates generally to the testing of semiconductor chips, and specifically to the design of an interposer for use in probe card assemblies.

Typically, semiconductor chips are tested to verify that they function appropriately and reliably. This is often done when the semiconductor chips are still in wafer form, that is, before they are diced from the wafer and packaged. This allows the simultaneous testing of many semiconductor chips at a single time, creating considerable advantages in cost and process time compared to testing individual chips once they are packaged. If chips are found to be defective, they may be discarded when the chips are diced from the wafer, and only the reliable chips are packaged.

Generally, modem microfabricated (termed MEMS) probe card assemblies for testing semiconductors have at least three components: a printed circuit board (PCB), a substrate to which thousands of probe contactors are coupled (this substrate hereinafter will be referred to as the “probe contactor substrate” and the probe contactor substrate together with the attached probe contactors hereinafter will be referred to as the “probe head”), and a connector which electrically interconnects the individual electrical contacts of the PCB to the corresponding electrical contacts on the probe contactor substrate which relay signals to the individual probe contactors. In most applications, the PCB and the probe head must be roughly parallel and in close proximity, and the required number of interconnects may be in the thousands or tens of thousands. The vertical space between the PCB and the substrate is generally constrained to a few millimeters by the customary design of the probe card assembly and the associated semiconductor test equipment. Conventional means of electrically connecting the probe contactor substrate to the contact pads of the PCB include solder connection, elastomeric vertical interposers, and vertical spring interposers. However, these technologies have significant drawbacks.

In the early days of semiconductor technology, the electrical connection between the probe contactor substrate and the PCB was achieved by solder connection. Solder connection technology involves electrically connecting an interposer to the PCB by means of melting solder balls. For instance, U.S. Pat. No. 3,806,801, assigned to IBM, describes a vertical buckling beam probe card with an interposer situated between the probe head (probe contactor substrate) and a PCB. The interposer is electrically connected to the PCB, terminal to terminal, by means of melting solder balls (see FIG. 1). Another example is seen in U.S. Pat. No. 5,534,784, assigned to Motorola, which describes another probe card assembly with an interposer that is solder reflow attached to a PCB by using an area array of solder balls. The opposite side of the interposer is contacted by buckling beam probes (see FIG. 2).

In both of these patents, an array of individual probe contactor springs is assembled to the interposer, either mechanically or by solder attachment, which use solder area array technology. However, this method has a number of significant disadvantages, particularly when applied to large area or high pin count probe cards. For instance, probe cards with substrate sizes larger than two square inches are difficult to solder attach effectively because both the area array interconnect yield and reliability become problematic. During solder reflow, the relative difference in thermal expansion coefficients between the probe contactor substrate and PCB can shear solder joints and/or cause mismatch-related distortion of the assembly. Also, the large number of interconnects required for probe cards make the yield issues unacceptable. Furthermore, it is highly desirable that a probe card assembly can be disassembled for rework and repair. Such large scale area array solder joints can not be effectively disassembled or repaired.

An alternative to solder area array interposers is the general category of vertically compliant interposers. These interposers provide an array of vertical springs with a degree of vertical compliance, such that a vertical displacement of a contact or array of contacts results in some vertical reaction force.

An elastomeric vertical interposer is an example of one type of a vertically compliant interposer. Elastomeric vertical interposers use either an anisotropically conductive elastomer or conductive metal leads embedded into an elastomeric carrier to electrically interconnect the probe contactor substrate to the PCB. Examples of elastomeric vertical interposers are described in U.S. Pat. No. 5,635,846, assigned to IBM (see FIG. 3), and U.S. Pat. No. 5,828,226, assigned to Cerprobe Corporation (see FIG. 4).

Elastomeric vertical interposers have significant drawbacks as well. Elastomeric vertical interposers often create distortion of the probe contactor substrate due to the forces applied on the probe head substrate as a result of the vertical interposer itself. Additionally, elastomers as a material group tend to exhibit compression-set effects (the elastomer permanently deforms over time with applied pressure) which can result in degradation of electrical contact over time. The compression-set effect is accelerated by exposure to elevated temperatures as is commonly encountered in semiconductor probe test environments where high temperature tests are carried out between 75° C. and 150° C. or above. Finally, in cold test applications, from 0° C. to negative 40° C. and below, elastomers can shrink and stiffen appreciably also causing interconnect failure.

A second type of vertical compliant interposer is the vertical spring interposer. In a vertical spring interposer, springable contacting elements with contact points or surfaces at their extreme ends extend above and below the interposer substrate and contact the corresponding contact pads on the PCB and the probe contactor substrate with a vertical force. Examples of such vertical spring interposers are described in U.S. Pat. No. 5,800,184, assigned to IBM (see FIG. 6) and U.S. Pat. No. 5,437,556, assigned to Framatome (see FIG. 5) (the Framatome patent does not describe a vertical probe card interposer but is a more general example of a vertical spring interposer).

However, vertical spring interposers have significant disadvantages as well. In order to achieve electrical contact between the PCB and the substrate with probe contactors, the interposer springs must be compressed vertically. The compressive force required for a typical spring interposer interconnect is in the range of 1 gf to 20 gf per electrical contact. The aggregate force from the multitude of vertical contacts in the interposer causes the Probe Contactor substrate to bow or tent since it can only be supported from the edges (or from the edges and a limited number of points in the central area) due to the required active area for placement of probe contactors on the substrate. The tenting effect causes a planarity error at the tips of the probe contactor springs disposed on the surface of the probe contactor substrate (see FIG. 7).

This planarity error resulting from vertical interposer compression forces requires that the probe contactor springs provide a larger compliant range to accommodate full contact between both the highest and the lowest contactor and the semiconductor wafer under test. The increase in compliant range of a spring, which such increase is roughly equal to the planarity error, requires that the spring be larger, with all other factors such as contact force and spring material being constant, and hence creates a deleterious effect on probe pitch.

Furthermore, probe contactor scrub is often related to the degree of compression, so the central contactors in the tented substrate will have different scrub than the outer contactors which are compressed less. Consistent scrub across all contactors is a desirable characteristic, which is difficult to achieve with vertical compliant interposers.

Thus a new design for an interposer is needed to overcome the deficiencies of the prior art.

### SUMMARY OF THE INVENTION

Embodiments of the present invention are directed to a laterally-compliant spring-based interposer for testing semiconductor chips that imparts minimal vertical force on a probe contactor substrate in an engaged state. Instead, the interposer contactor spring elements engage contact bumps in a lateral manner and thus exert lateral force against the contact bumps on the PCB and the probe contactor substrate when in an engaged state. Because the interposer springs impart minimal vertical force, they do not appreciably distort or tent the interposer substrate, thus enabling improved planarity of the probe contactors and better electrical connections with the contact bumps built on the PCB and probe contactor substrate.

Embodiments of the present invention, generally include an interposer substrate with at least one laterally compliant spring element (i.e. the resilient contact element) having an upper and a lower portion. The upper portion extends vertically above the upper surface of an interposer substrate or holder assembly and the lower portion extends vertically below the lower surface of interposer substrate or holder assembly. It should be noted here that the term “substrate” is meant to include any type of structure from which a laterally compliant spring element extends. As will be discussed below, the structure may be a monolithic substrate, with or without vias, a ceramic strip to which laterally compliant elements are attached, a holder assembly, or any other type of structure from which laterally compliant spring elements may extend. The upper and lower portions may be electrically connected by an electrically conductive via that extends through an interposer substrate, or the resilient contact element may be a monolithic structure having an upper and lower portion which are joined together by a middle portion, the whole of which extends through a hole in the substrate or holder assembly. In the latter embodiment the middle portion may pass through the substrate. The upper and lower portions of the resilient contact element are designed to be laterally resilient. In an embodiment of the present invention, the laterally compliant spring element may be substantially vertically rigid, and in other embodiments, the laterally compliant spring element may be vertically compliant. The spring elements have contact regions (which engage the contact bumps) on a side of the spring element, as opposed to the spring element's vertical extremity as is the case with vertical spring interposer elements.

In semiconductor test probe card construction, the interposer is disposed between a PCB and a probe contactor substrate. In an unengaged state, an upper contact region of the upper portion of the resilient contact element and a lower contact region of the lower portion of the resilient contact element are not in contact with the protruding contact bumps on the PCB or probe contactor substrate. Thus, in the unengaged state, the interposer may not electrically interconnect the PCB and the probe contactor substrate.

In an engaged state, the interposer electrically interconnects the PCB and the probe contactor substrate by contacting the sides of the bumps on both substrates with a substantially lateral force. Because the force involved is substantially lateral (horizontal in a direction substantially parallel with the probe contactor substrate and the PC B) instead of vertical, they do not appreciably distort or tent the substrate, and they ensure greater planarity and better electrical connections with the contact bumps built on the substrate.

Another embodiment of the proposed invention utilizes a flexible wiring board technology (commonly known as “flex circuit”) or its functional equivalent as a foundation for forming linear arrays of lateral contact elements. The contact elements are formed from conductive metal traces on or in a flexible substrate (usually a plastic). The plastic laminate material itself forms the base or substrate on which the conductor is formed and also provides part of the resiliency required in the lateral interposer contact element. The metal conductor also provides resiliency and compliance, which in combination with the flex substrate forms the complete lateral spring. Strips of lateral contacts may be combined in an assembly to form a two dimensional array of lateral contacts. These strips may be mounted into a carrier plate such as a slotted ceramic substrate which holds the strips in their correct aligned position and also provides mechanical support to engage the lateral springs against their corresponding contact bumps. This embodiment incorporating flex circuitry allows for simplified and reduced cost manufacturing, improved signal shielding, impedance control, and supply and ground isolation from signal transients.

While the preferred embodiment of the present invention is directed to an interposer for use in a probe card assembly for testing semiconductor chips, the present invention may be used in many applications wherein an interposer substrate is used to connect two substantially parallel electrical wiring substrates.

### BRIEF DESCRIPTION OF THE DRAWINGS

FIGS. 1-7 illustrate examples of prior art in the probe card interposer field.

FIG. 8A illustrates a side view of an embodiment of the present invention in an unengaged state.

FIG. 8B illustrates a side view of an embodiment of the present invention in an engaged state.

FIG. 9A illustrates a side view of an embodiment of the present invention in an unengaged state.

FIG. 9B illustrates a perspective view of an embodiment of the present invention.

FIG. 10A illustrates a side view of a probe card assembly utilizing an embodiment of the present invention in an unengaged state.

FIG. 10B illustrates a side view of a probe card assembly utilizing an embodiment of the present invention in an engaged state.

FIG. 11 illustrates a side view of an embodiment of an engagement mechanism for engaging an array of lateral contactors with their associated bumps.

FIG. 12A illustrates a side view of an embodiment of the present invention in an unengaged state.

FIG. 12B illustrates a side view of an embodiment of the present invention in an engaged state.

FIG. 12C illustrates a side view of an embodiment of the present invention.

FIG. 13 illustrates a side view of an embodiment of the present invention in an engaged state.

FIG. 14 illustrates a side view of an embodiment of the present invention in an engaged state.

FIG. 15 illustrates a side view of an embodiment of the present invention in an engaged state.

FIG. 16 illustrates a lateral spring contactor assembly according to an embodiment of the present invention.

FIG. 17 illustrates a lateral spring contactor assembly according to an embodiment of the present invention.

FIG. 18 illustrates a strip carrier according to an embodiment of the present invention.

FIG. 19 illustrates lateral spring contactor assembly with strip carriers in an alignment frame according to an embodiment of the present invention.

FIG. 20 illustrates a batch microfabricated strip of lateral contactors according to an embodiment of the present invention.

FIG. 21A illustrates examples of side views of contact regions on spring elements according to an embodiment of the present invention.

FIG. 21B illustrates examples of front views of contact regions on spring elements as shown in FIG. 21A.

FIG. 22 illustrates side views of contact bumps according to embodiments of the present invention.

FIG. 23A illustrates a side view of another embodiment of the present invention in an unengaged state.

FIG. 23B illustrates a front view of another embodiment of the present invention in an unengaged state.

FIG. 24 illustrates a side view of a probe card assembly utilizing an embodiment of the present invention in an unengaged state.

FIGS. 25A-C illustrate a process for forming an embodiment of the present invention as illustrated in FIG. 12C.

FIGS. 26A-E illustrate a process for forming an embodiment of the present invention as illustrated by FIG. 20.

FIG. 27A illustrates a front view of an embodiment of the present invention utilizing flex circuitry.

FIG. 27B illustrates a top-down view of an embodiment of the present invention utilizing flex circuitry.

FIG. 27C illustrates a side view of an embodiment of the present invention utilizing flex circuitry.

FIG. 28A illustrates a front view of an embodiment of the present invention utilizing flex circuitry in an engaged state.

FIG. 28B illustrates a top-down view of an embodiment of the present invention utilizing flex circuitry in an engaged state.

FIG. 28C illustrates a side view of an embodiment of the present invention utilizing flex circuitry in an engaged state.

FIG. 29A illustrates a front view of an embodiment of the present invention utilizing flex circuitry and flex paddles.

FIG. 29B illustrates a side view of an embodiment of the present invention utilizing flex circuitry and flex paddles.

FIG. 30A illustrates a front view of an embodiment of the present invention utilizing flex circuitry and grounded shield strips.

FIG. 30B illustrates a side view of an embodiment of the present invention utilizing flex circuitry and grounded shield strips.

FIG. 31A illustrates a front view of an embodiment of the present invention utilizing flex circuitry in a ground-signal-ground format.

FIG. 31B illustrates a side view of an embodiment of the present invention utilizing flex circuitry in a ground-signal-ground format.

FIG. 32A illustrates a front view of an array of lateral contactors in a slotted carrier substrate according to an embodiment of the present invention.

FIG. 32B illustrates a top-down view of an array of lateral contactors in a slotted carrier substrate according to an embodiment of the present invention.

FIG. 32C illustrates a side view of an e array of lateral contactors in a slotted carrier substrate according to an embodiment of the present invention.

FIG. 33A illustrates a front view of an array of lateral contactors in a slotted carrier substrate with on-board wiring according to an embodiment of the present invention.

FIG. 33B illustrates a top-down view of an array of lateral contactors in a slotted carrier substrate with on-board wiring according to an embodiment of the present invention.

FIG. 33C illustrates a side view of an e array of lateral contactors in a slotted carrier substrate with on-board wiring according to an embodiment of the present invention.

FIG. 34 illustrates a side view of an embodiment of the present invention utilizing flex circuitry and laminated/plated/bonded mechanical backing.

FIG. 35 illustrates a front view of an embodiment of the present invention utilizing flex circuitry incorporating electrical components.

FIG. 36A illustrates a front view of an embodiment of the present invention utilizing flex circuitry having tailed contact areas.

FIG. 36B illustrates a side view of an embodiment of the present invention utilizing flex circuitry having tailed contact areas.

FIG. 37 illustrates an embodiment of the present invention utilizing serpentine paddles.

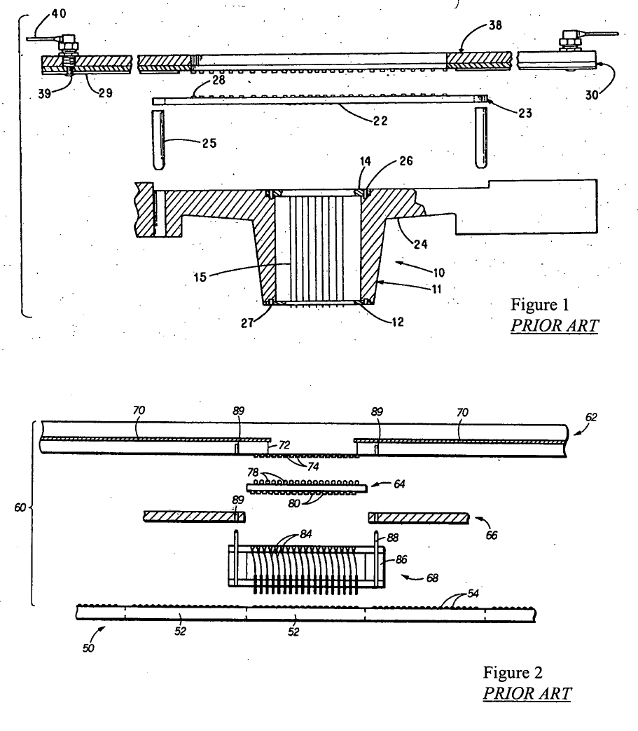

### DETAILED DESCRIPTION

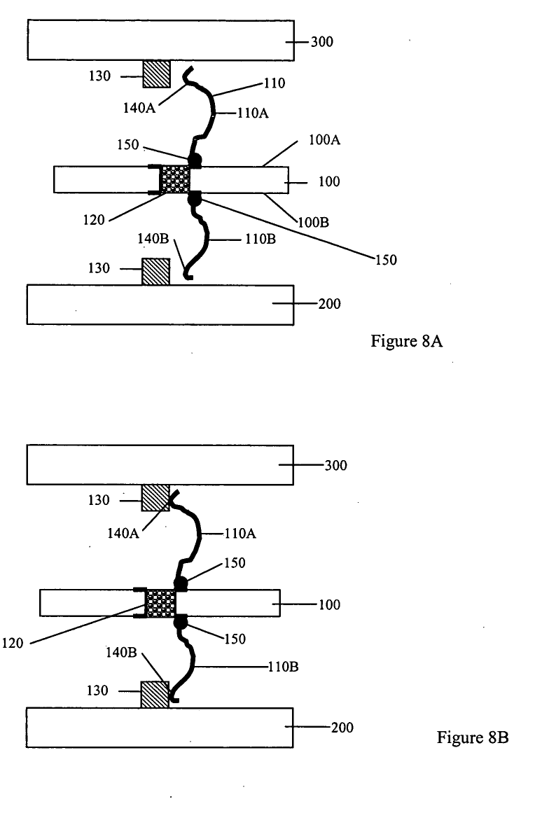

FIG. 8A depicts an embodiment of the present invention. It illustrates a laterally compliant interposer according to an embodiment of the present invention in an unengaged state. In this embodiment an interposer substrate 100, has upper surface 100A and a lower surface 100B. A resilient contact element 110 has an upper portion 110A and a lower portion 110B, which are electrically coupled together by way of a via 120 that extends through the interposer substrate 100. The upper portion 110A extends substantially vertically from the upper surface 100A, and the lower portion 110B extends substantially vertically from the lower surface 100B. As illustrated in FIG. 8A, the via 120 is substantially vertical, however it may also have horizontal qualities as well such as surface or buried conductive traces, as is the case of space transformers which are known in the art.

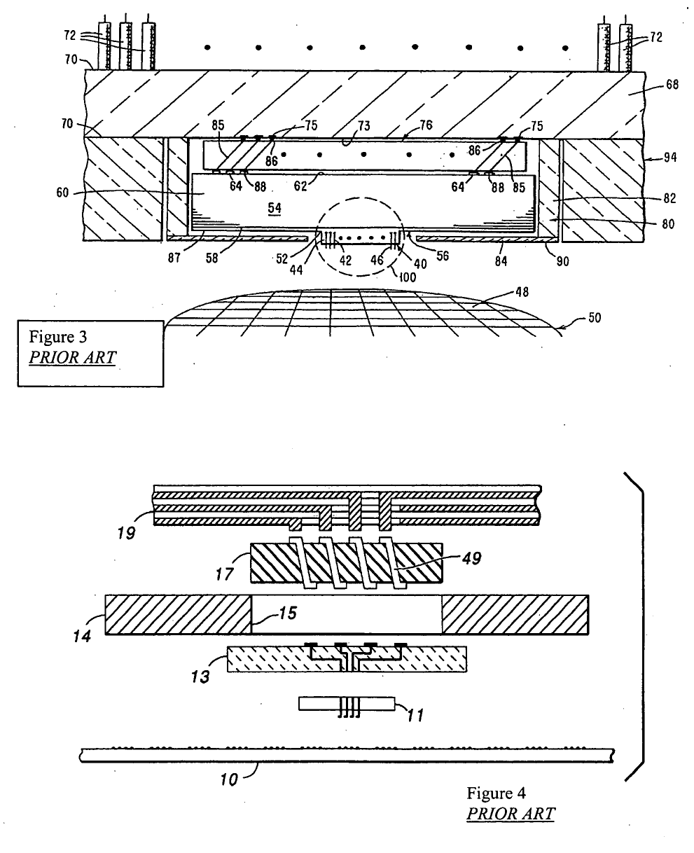

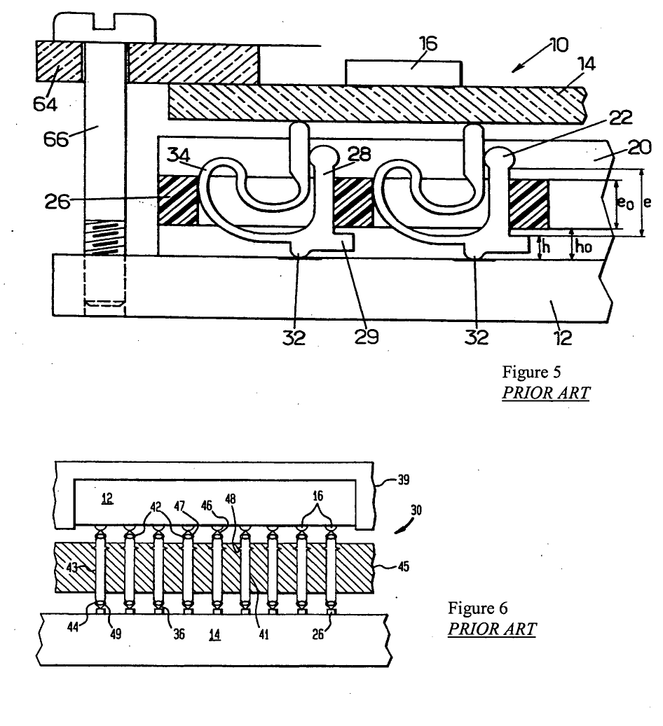

The upper portion 110A and the lower portion 110B have the quality of being substantially compliant in a lateral (horizontal) direction. The upper portion 110A of the laterally compliant spring element 110 may have an upper contact region 140A, and the lower portion 110B of the laterally compliant spring element 110 may have a lower contact region 140B. The contact regions 140A, 140B make lateral contact with the sides of the contact bumps 130 of the upper 300 and lower 200 substrates when in an engaged state (as seen in FIG. 8B). The contact regions 140A, 140B are substantially on the sides of the upper 110A and lower 110B portions of the laterally resilient contact element 110. This is in sharp contrast to a vertically resilient contact element as known in the art (See FIGS. 3-6) wherein the contact regions are on the vertically resilient contact element's vertical or linear extremity. Vertical or linear extremity here is meant as the termination point of the upper or lower portion, not necessarily where the upper or lower portion is at its greatest height. The contact regions 140A, 140B may be at the greatest height of the upper 110A and lower 110B portions, as the upper 110A and lower 110B portions may be bent, angular, or serpentine and the termination point of the upper 110A or lower 110B portions may be at a lesser height than that of the contact regions 140A, 140B.

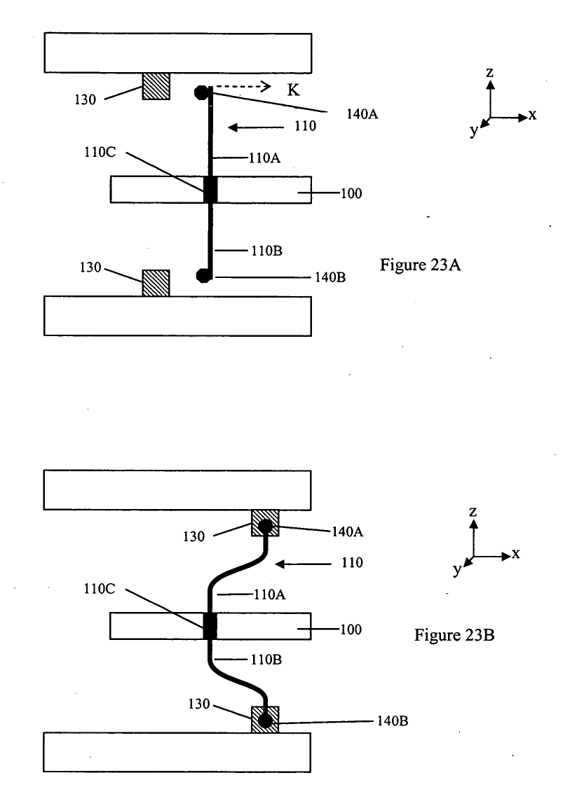

FIGS. 23A and 23B, illustrate an embodiment of the present invention wherein the upper and lower portions 110A, 110B both bend and twist when they contact the contact bumps 130. This configuration allows for more mechanical spring length and a more efficient spring than a simple bending spring as shown in other figures. In FIG. 23A (a side view of the laterally compliant spring element 110), the laterally compliant spring element 110 is shown in an unengaged state. When the contact regions 140A, 140B contact the contact bumps 130 they will travel in the direction noted by the arrow K. In FIG. 23B, the upper and lower portions 110A, 110B will bend towards the “y direction,” denoted by the Cartesian coordinate diagram, while at the same time twisting about an axis. As illustrated, upper and lower portions 110A, 110B which are serpentine in shape are more likely to exhibit such twisting properties. Though not shown in the FIGURE, additional mechanical constraints may be added to the structure to limit bending motion in favor of pure twisting (torsional) motion if desired.

The upper 110A and lower 110B portions may be coupled to the via 120 by means of lithographically plating the portions 100A, 100B to the via 120. Alternatively, the upper 110A and lower 110B portions may be soldered to the via 120 with solder balls 120. Yet another embodiment is for upper portion 110A and lower portion 110B to be coupled to the via using any other bonding mechanism or retaining feature known in the art such as thermosonic and thermocompression bonding, conductive adhesive attachment, laser welding, or brazing. Such upper 110A and lower 110B portions may be made in any suitable fashion such that they have the properties of being laterally resilient. They may be formed by wire bonding and overplating, or by lithographic electroforming techniques known in the art. Examples of lithographic techniques are disclosed in U.S. patent application Ser. Nos. 11/019,912 and 11/102,982, both of which are assigned to Touchdown Technologies, Inc and are incorporated herein.

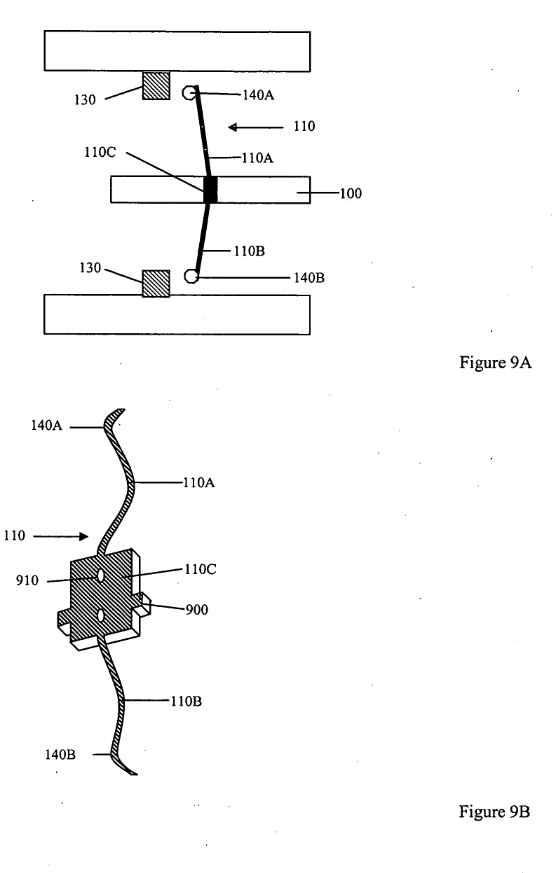

The laterally compliant spring element 110 may also be monolithic. In this case, as shown in FIGS. 9A and 9B, 12C and 16, the upper 110A and lower 110B portions are electrically coupled together by way of a middle portion 110C. The middle portion 110C passes the electrical signals between the upper 110A and lower 110B portions through the interposer substrate 100 as well as providing a substantially rigid region for handling and attachment to a substrate or other suitable carrier. Such a laterally compliant spring element 110 may have a thick middle portion 110C and thinner upper 110A and lower 110B portions. The middle portion 110C may also have alignment features 900 (for aligning the laterally compliant spring element 110 in the interposer substrate 100) and retaining features 910 (for retaining the laterally compliant spring element 110 in the interposer substrate 100). An alignment feature 900 may also function as a retaining feature 910, and vice versa. An example of an aligning feature may be a dowel pin hole that mates to a pin or a notch or shoulder that mates to another part. A retaining feature may be a shoulder or protrusion that is captured between two parts thus holding it in place.

A monolithic laterally compliant spring element 110 may be formed from a stamped spring. Such a spring may be made of any formable spring material including Beryllium Copper, Bronze, Phosphor Bronze, spring steel, stainless steel, wire or sheet stock, etc. Monolithic laterally compliant spring elements 110 may also be formed by lithographic electroforming techniques. Lithographically electroformed elements 110 may be fabricated to very precise tolerances. Materials which can be electroformed conveniently include Ni, grain stuffed Ni, Ni alloys including Ni and NiCo, W, W alloys, bronze, etc. A further advantage of lithographic electroforming is that the contact regions 140A, 140B (or alternatively the entire element 110) can be well defined and conveniently coated with an appropriate contact metal, such as gold, silver, Pd—Co, Pd—Ni, or Rh. The contact regions 140A, 140B may also be coated by means other than plating (for example, vacuum coated) with a conductive contact material such as TiN or TiCN.

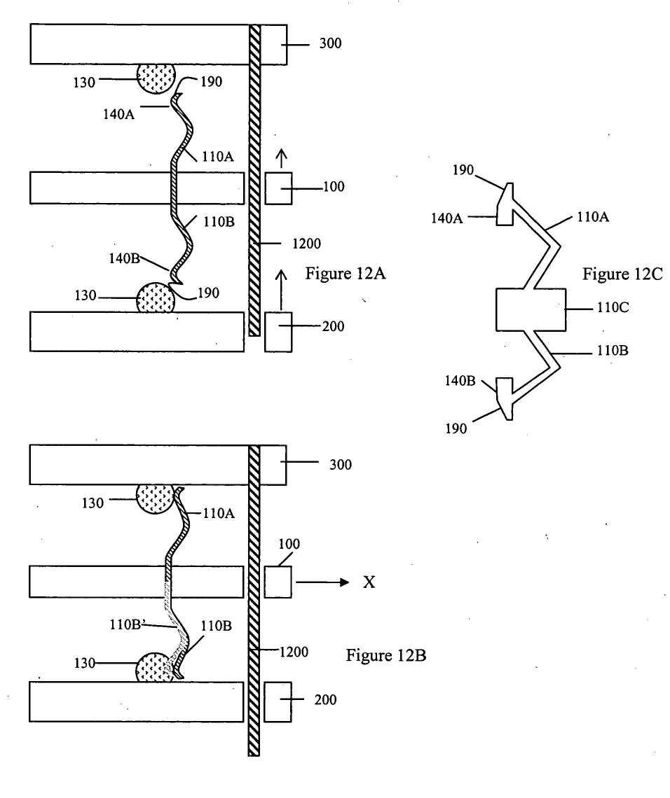

FIGS. 25A-25C illustrate cross sections at various stages of a process for forming a laterally compliant spring element 110 by lithographic electroforming techniques. In FIG. 25A, a substrate (a) is coated with a sacrificial metal (b) (which may also be a sacrificial polymer coated with a conductive plating seed layer). The sacrificial layer is coated with a mold polymer (c) which is patterned in the negative image of the spring contactor to be formed (PMMA by x-ray lithography, or photoresist by UV lithography or other appropriate means) and the mold is filled with a spring metal (d) such as a Ni alloy. At this stage, the top surface of the photoresist (c) and spring metal (d) may be planarized by mechanical grinding, lapping or machining. In the second sequence, the same cross section is shown with the polymer mold (c) stripped away (for example by solvent stripping or plasma ashing) and the exposed parts of the spring metal (d) are overcoated with metal layers appropriate for electrical contact and conduction (for example Cu, Au, Ru, Rh, PdCo or a combination). Finally, the spring elements are released from the substrate (a) by dissolving the sacrificial layer (b). This dissolution of the sacrificial metal is performed in such a way as to not damage the spring metal (d) or metal coatings. FIGS. 25A-25C illustrate the forming of a laterally compliant spring element illustrated in FIG. 12C.

FIG. 12C shows a microformed laterally compliant spring element that has a compliant direction that is parallel to the sacrificial substrate on which the contactor was formed (that is parallel to the plane of the contactor). FIG. 18 shows a microformed laterally compliant spring element with a compliant direction normal to the plane of the sacrificial substrate (that is normal to the plane of the contactor). In the creation of any monolithic laterally compliant spring element 110, the laterally compliant spring element 110 may be fabricated with differing thickness and features on different areas so as to optimize the spring characteristics and mechanical characteristics of the contact regions 140A, 140B, the upper and lower portions 110A, 110B and the middle portion 110C.

A further technique of fabricating a monolithic laterally compliant spring element 110 is by a hybrid of conventional machining and lithographic electroforming techniques whereby part of the laterally compliant spring element 110 is lithographically electroformed on spring stock material which is subsequently further shaped and released by stamping, punching, laser cutting, abrasive jet cutting or similar techniques. Such a hybrid technique allows the use of sheet spring stock (which has excellent mechanical spring characteristics) as the spring material and microformed metals for further refinement of contact shape and micro-alignment features.

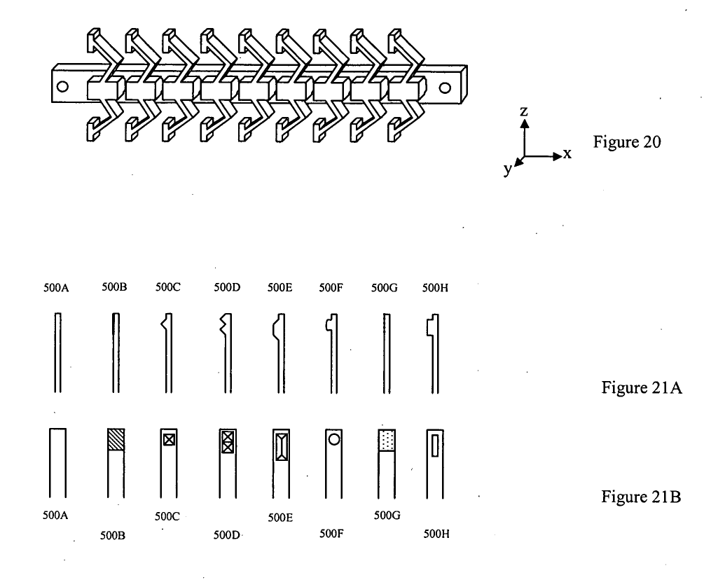

The contact regions 140A, 140B may have different surface configurations as shown in FIGS. 21A and 21B. For clarification purposes, FIG. 21A shows side views of the contact features, while front views (looking at the contact feature head on) are shown in FIG. 21B The contact region 140A, 140B may be have a flat contact surface 500A, a flat contact surface with a selective contact material coating 500B, or the contact region 140A, 140B may have a surface feature designed to dig into the bump 130, skate on the surface of the bump 130, or otherwise scrub the contacting surface of the bump 130. Other features that may be formed on the contact regions 140A, 140B include a pyramid or point shaped contact 500C, a multipoint contact 500D, a pyramid blade type contact 500E, a ball or rounded shaped contact 500F, a roughened surface contact 500G, or a flat blade (or multiple flat blades) surface contact 500H. This list is not intended to be exhaustive, but rather merely shows examples of the more common surface features.

A contact feature 500A-500H may be selected to provide stable and low electrical contact resistance to the particular bump geometry (different bump geometries as discussed below) and metallurgy with a minimum of lateral force. These contact features 500B-500H may be applied to the surface by stamping, mechanical processing, chemical etching, electrochemical machining, and lithographic microfabrication including electroforming, laser machining, bump bonding, wire bonding and the like. The contact feature 500A-500H may be coated with an appropriate contact material as already described and/or the features may be made of a separate material selected for its contact characteristics.

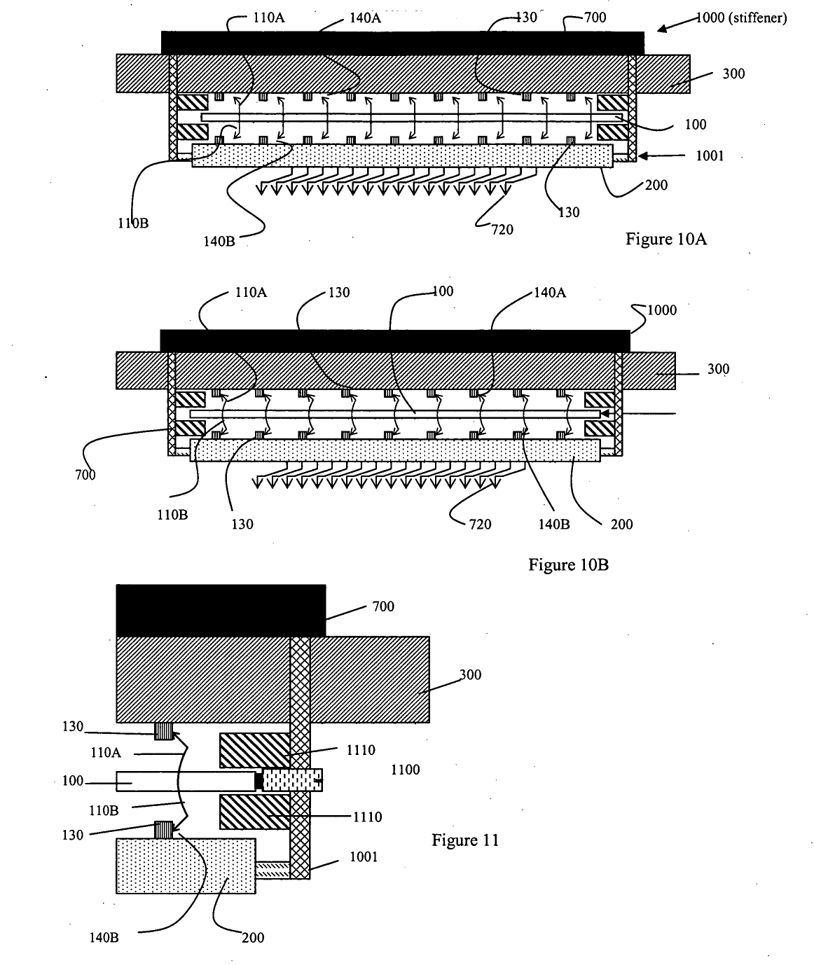

In an embodiment of the present invention, the interposer substrate 100 (or interposer array assembly 800) is used to create a probe card assembly 1000 as seen in FIGS. 10A and 10B. The probe card assembly generally has an upper substrate 300 (which is generally referred to as a printed circuit board (PCB)) and a lower substrate 200 (which is generally referred to as a probe head or probe contactor substrate because it carries the probe elements 720 which contact the wafer). While the present invention is particularly well suited to semiconductor test probe cards, the invention is generally applicable to interconnecting any two wiring substrates. At least one incarnation of the present invention may be considered a specialized very high density Zero Insertion Force (ZIF) area array connector. Most ZIF connectors are designed for package-level and printed wiring board densities where area array pitches (the pitch between laterally compliant spring contact elements 100) are on the order of 1 mm or greater, however the present invention provides for pitches between 50 um and 1 mm.

FIG. 10A shows a probe card assembly 1000 in an unengaged state, that is, the interposer substrate 100 is not in a position wherein the contact regions 140A, 140B are contacting the contact bumps 130 of the upper 300 and lower 200 substrates. In FIG. 10A, the interposer substrate 100 (or interposer array assembly 800), the lower substrate 200, and the upper substrate 300 are mounted together using a stiffener 700 and mount mechanism 1001 so that the individual substrates 100, 200, 300 are substantially parallel. The stiffener 700 and mount mechanism 1001 may be of any form known in the art such as kinematic mounts that provide a metal frame around the probe contactor substrate which is forced towards the PCB by leaf springs against adjustment screws (see U.S. Pat. No. 5,974,662), adhesive mounts which provide for a rigid and permanent attachment of the substrates 100, 200, 300 to mating features on the mount, and attachment to a hard stop on the mount by means of screws or similar fasteners. The particular means of attaching the substrates 100, 200, 300 to the stiffener 700 is not of particular relevance to this invention so long as it provides for a mechanically stable fixture between the probe card assembly 1000 and the interposer substrate 100.

In the unengaged state as shown in FIG. 10A, the interposer substrate 100 is arranged so that the upper 110A and lower 110B portions are situated next to the contact bumps 130, but the contact regions 140A, 140B are not in contact with the contact bumps 130 on the adjacent substrates 200, 300. The arrangement is termed the unengaged state because the interposer substrate 100 is not yet engaged to make electrical contact between the opposing sets of bumps 130. In the unengaged state, the interposer substrate 100 may be attached to the stiffener 700 in a position which is substantially parallel to the upper substrate 300 reference plane (typically understood to mean the surface of the PCB or some set of features on the stiffener 700), and at a separation from the upper substrate 300 so that the contact regions 140A, 140B are aligned to their corresponding bumps 130, but not in contact with them.

To engage the interposer substrate 100, a lateral or sideways force is applied by a lateral engagement element 1100 to the interposer substrate 100, causing the interposer substrate 100 to move in a lateral fashion and engage the contact regions 140A, 140B with their corresponding bumps 130. This lateral engagements element 1100 may be screws, differential screws, cams, or other appropriate machine elements known in the art of mechanical assembly and alignment, as shown in FIG. 11. This fully engaged position is shown in FIG. 10B. The movement of the interposer substrate 100 may be constrained so that it free to move in a lateral direction (X direction in the plane of the substrates for example) without incurring movement substantially up or down (Z direction in Cartesian coordinates) or side to side (Y direction in Cartesian coordinates), and without rotating. This constraint may be provided by interposer constraint elements 1110 such as interposer guides, flexures, slide bearings, bushing guides, etc.

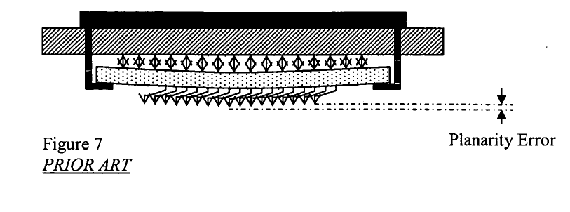

Because the contact regions 140A, 140B contact the bumps 130 of the upper 300 and lower 200 substrates at a side of the bumps 130, and thus only substantially impart lateral forces to the bumps 130, this interposer design does not create substantial vertical deflection (or tenting) of the substrates as shown in FIG. 7. Thus, this interposer design allows a probe card assembly 1000 with a higher degree of planarity as compared to vertical interposer technologies. Typical upper 110A and lower 110B portions may allow for lateral compliance (or design displacement) in the range of 10 um to 500 um, but preferably, the lateral compliance is approximately 200 um. The upper 110A and lower 110B portions may provide a lateral contact force to the bumps 130 in the range of 0.2 gf to 20 gf, and preferably they provide a lateral force to the bumps 130 of approximately 5 gf.

The upper 110A and lower 110B portions should be made to an appropriate length such that the finished assembly meets the design requirement. For example, the design requirement may call for a maximum distance of 10 mm between a bottom surface of the upper substrate 300 and the tips of the probe contactors 720. In this case, if the probe contactor substrate is 5 mm thick and the probe contactors 720 are 0.25 mm tall, the distance between the bottom of the upper substrate 300 and the top of the probe contactor substrate should be 4.75 mm. The upper 110A and lower 110B portions then are selected such that the contact regions 140A, 140B will touch the bumps 130 in an appropriate location while still providing enough clearance between the ends of the upper 110A and lower 110B portions and the opposing substrates. This clearance may be 100 um on each end leaving the total laterally compliant spring element length (including upper portion 110A and lower portion 110B) at about 4.55 mm. The bumps 130 may be 25 um to 750 um tall and preferably about 250 um tall. In this example, a bump 130 may have a bump contact region (where the contact regions 140A, 140B of the laterally compliant spring element 110 contacts the bump 130) of about 100 um from its base on the substrate 200, 300, and the additional height is intended to accommodate manufacturing and alignment tolerances.

Another embodiment utilizes laterally compliant spring elements 110 which are designed to initially engage the bumps 130 vertically, but once engaged, the laterally compliant spring elements 110 impart only a lateral force to the bumps 130. An embodiment of such a design is illustrated in FIGS. 12A-12C. In this design, the laterally compliant spring elements 110 are similar to those previously disclosed, except that they have an added feature termed a “lead-in element” 190. The lead-in element 190 may be a sloped surface on the upper 110A and lower 110B portions closer to the linear extremity of the upper 110A and lower 110B portions than where the contact regions 140A, 140B are located. This lead-in element 190 is designed to slide along the surface of the bump 130, translating vertical engagement motion into a lateral deformation of the upper 110A or lower 110B portion. A vertical force (in the range of 2 to 20 gf per contact during engagement) is required to assemble this type of probe card assembly 1000, but once engaged, there is zero-net vertical force on the substrates 100, 200, 300, and only a lateral force (denoted by arrow X in FIG. 12B) exists which is constrained by the guide 1200 which is in turn supported by the substrate 300 or directly by the stiffener 700. Suitable constraints (as indicated by the guide pin 1200) may include linear bearings, sliding surfaces, dowel pins, leaf springs, flexures etc. This form of assembly may not be termed a ZIF interposer, but is a Zero “holding force” interposer in that a vertical force is not imparted on the substrates 200 and 300 after engagement. FIG. 12A illustrates this embodiment in an unengaged state. FIG. 12B shows the same embodiment in an engaged state. In FIG. 12B, reference numeral 110B′ denotes the location of the lower portion 110B if the lead-in element 190 did not slide across the surface of the bump 130. In this type of assembly, the upper 300, interposer 100, and lower 200 substrates may all be aligned to one another (for example by the use of dowel pins 1200 through the three substrates 100, 200, 300) and then forced together vertically in order to engage the laterally compliant spring elements 110.

The use of laterally compliant spring elements 110 which initially vertically engage the bumps 130 provides for the possibility of forming an assembly which once engaged has balanced lateral forces and therefore requires no net lateral restraint (i.e. does not impart the force X shown in FIG. 12B). FIG. 13 shows such a case of a balanced lateral force assembly. The balanced lateral force assembly is accomplished by orienting the upper 110A and lower 110B portions of two different laterally compliant spring elements 110 and their associated bump 130 in a way such that the upper and lower portions 110A, 110B of the two different laterally compliant spring elements 110 deflect in opposing directions. It is contemplated that the laterally compliant spring elements 110 may be oriented in any z-axis orientation so long as the net lateral force (sum of all the lateral force vectors from all laterally compliant spring elements 110) is at or near zero.

The same idea of a balanced lateral force may be applied to the case of a single monolithic laterally compliant spring element 110, as opposed to two laterally compliant spring elements 110. In this case, the laterally compliant spring elements 110 resemble a pin-and-socket type of connector such as those shown in FIGS. 14 and 15. In this form, the laterally compliant spring element 110 has at least two of both the upper 110A and lower 110B portions. The dual upper 110A and lower 110B portions are generally oriented symmetrically around the vertical axis of the laterally compliant spring element 110. Such a single, “force-balanced” laterally compliant spring element 110 may be designed to contact a contact bump 130 by either capturing at least a portion of the contact bump 130 between the dual (or more than two) upper 110A or lower 110B portions (as shown in FIG. 14), or by inserting the dual upper 110A or lower 110B portions into a hole in the contact bump 130 (as shown in FIG. 15). Several key elements of such a pin-and-socket type connector is that they provide a lead-in feature 190, a contact region 140A, 140B, a plurality of upper 110A and lower 110B portions which deform to provide lateral compliance, and some amount of vertical engagement range (the pin and socket maintain electrical contact through a range of vertical engagement).

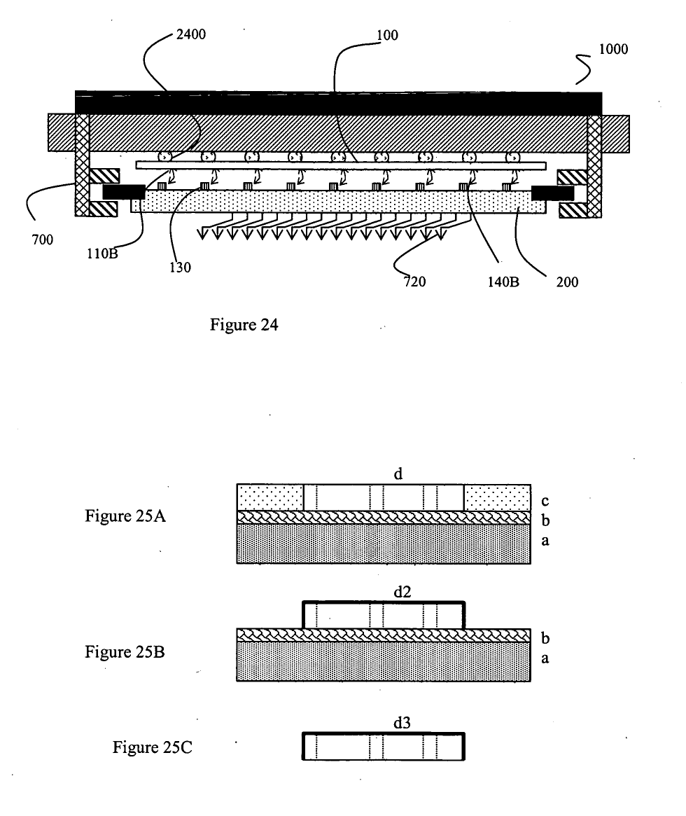

A further embodiment is illustrated in FIG. 24. In FIG. 24, the upper portion 140A of the laterally compliant spring element has been replaced by direct attachment elements 2400. The direct attachment elements 2400 are elements which directly attach the interposer substrate 100 to upper substrate 300. Such direct attachment elements may be solder balls, solder bumps, anisotropically conductive adhesive, or any other conductive area array attachment technique known in the art of electronic packaging. In this embodiment, the engagement of the interposer is achieved by lateral translation of the lower substrate 200, relative to the entire remaining probe card assembly. All descriptions relevant to the translation mechanism of the interposer substrate 100 in the embodiments shown in FIGS. 10A and 10B and 11 are applicable in this embodiment to the lower substrate 200. The same embodiment of FIG. 24 may be practiced by direct attachment elements 2400 attaching the interposer substrate 100 to the lower substrate 200 instead of the upper substrate 300.

The embodiment of the FIG. 24 may be further simplified by the removal of the interposer substrate 100 all together. In this case a laterally compliant spring element 110 (now having only one of either an upper portion 110A or a lower portion 110B) is directly attached to either the upper or lower substrates 300, 200. The practical element is still the same in that the laterally compliant spring element 110 will engage a contact bump 130 at a side of the contact bump 130.

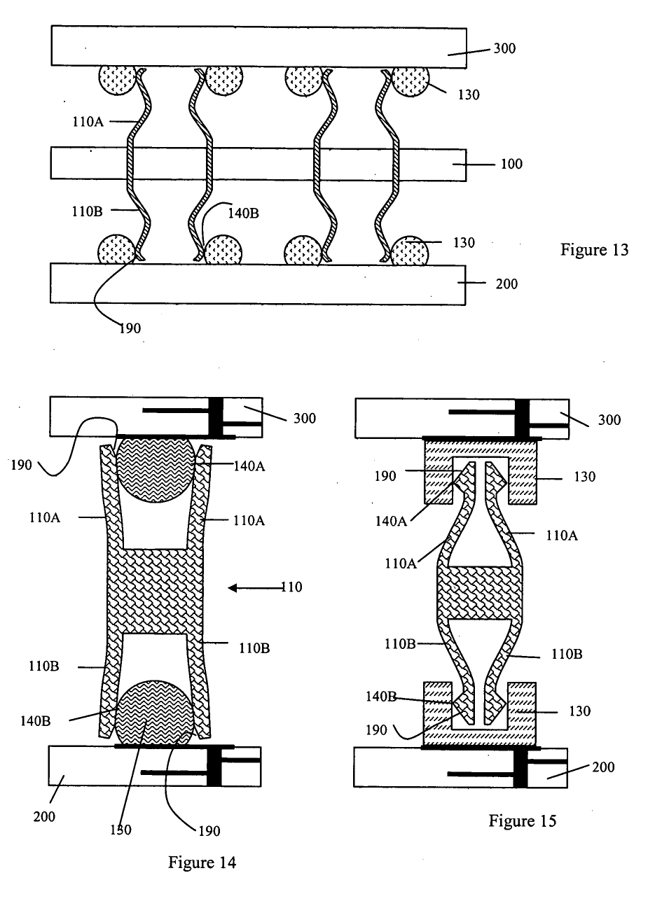

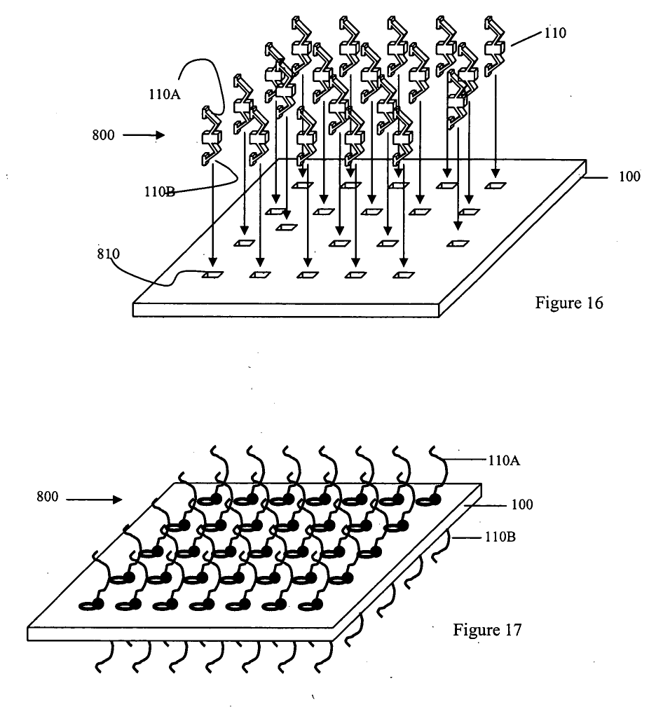

Any of the above-mentioned embodiments of laterally compliant spring elements 110 may be assembled into an array 800 as seen in FIGS. 16 and 17. The array 800 is a interposer substrate 100 with a plurality of laterally compliant spring elements 110. One method of forming an array is to provide an interposer substrate 100 with predefined, machined holes 810 which accept and retain the laterally compliant spring elements 110 in an appropriate position for contacting the contact bumps 130. Such an interposer substrate 100 may be made of ceramic, plastic, glass dielectric coated Si, dielectric coated metal, or any other appropriate insulating material or combination of materials. The machined holes 810 may be machined by laser machining techniques, mechanical drilling, chemical etching, plasma processing, ultrasonic machining, molding, or any other known machining techniques.

Preferably the interposer substrate 100 has the property of a thermal expansion coefficient that is matched or close to that of the two wiring substrates 200, 300 to be interconnected. In the case where the two wiring substrates 200, 300 have dramatically different thermal expansion coefficients, the interposer substrate 100 may have a thermal expansion coefficient selected to match that of one or the other wiring substrates 200, 300, or it may have an intermediate thermal expansion coefficient so as to “share” the thermal mismatch effect between the two wiring substrates 200, 300. Using such an array 800, allows the assembly of laterally compliant spring elements in essentially arbitrary patterns and provides design flexibility in placement of the contact bumps 130 on the wiring substrates 200, 300.

As discussed before, the interposer substrate 100 and the laterally compliant spring elements 110 may have additional features designed to capture and hold the laterally compliant spring elements 110 in place within the interposer substrate 100. Such features may comprise retainer tabs, springs on the middle portion 110C of the laterally compliant spring element 110, stepped holes in the interposer substrate 100, etc. The laterally compliant spring elements 110 may also be freely placed in the interposer substrate 100 or they may be bonded in place with adhesives, solder or any other suitable bonding agent.

Another way of forming an array 800 is to attach the upper 110A and lower 110B portions of a laterally compliant spring element 110 to either side of the interposer substrate 100, as shown in FIG. 17. Such an array 800 may be conveniently formed using ceramic technology such as LTCC (Low Temperature Cofired Ceramics) or HTCC (High Temperature Cofired Ceramics) for the interposer substrate 100. Interposer substrates 100 for this method may be formed form laser drilled and via-metalized substrates, plated or plugged ceramics such as those produced by Micro Substrates of Tempe, Ariz., the use of PCB technology, or electroplated metal vias in etched and oxidized silicon. Once the interposer substrate 100 is produced with conductive vias 120, the upper 110A and lower 110B portions of the individual laterally compliant spring elements 110 may be attached to the top surface 100A and the bottom surface 100B of the substrate 100 by any convenient means including thermosonic and thermocompression bonding, solder attach, conductive adhesive attach, laser welding or brazing. They may also be lithographically plated. In this method of forming an array 800, the upper portion 110A and lower portion 110B do not have to be placed in direct opposition to one another (that is directly on either side of substrate 100). Rather, they may be placed at arbitrary locations on either side of substrate 100 and electrically interconnected through conductive traces both on the surfaces of and buried within as well as vias through substrate 100.

The laterally compliant spring elements 110 may alternatively be assembled into an array 800 by first assembling them into strips 1800 or linear arrays on holders as shown in FIG. 18. The strips 1800 may be made of materials similar to the single interposer substrate 100 mentioned above. The strip 1800 may include various alignment aids 1820 such as an alignment surface, and attachment aids 1830 such as solder or adhesive. The individual laterally compliant spring elements 110 may be fitted to the strip 1800 loosely, or they may be assembled with adhesive, solder, alignment pins, spring retainers, or other suitable means. For example in FIG. 18, the individual laterally compliant spring elements 110 are adhesively bonded to the strip 1800. The laterally compliant spring element 110 is placed up against an alignment surface 1820 without any intervening adhesive material. The adhesive 1830 is placed in a cavity which provides for an appropriate adhesive bond line. The individual laterally compliant spring elements 110 may also be fabricated in groups with temporary tabs joining the springs for easier assembly and accurate relative alignment. Once assembled to the carrier, such temporary tabs could be removed mechanically or by laser etching.

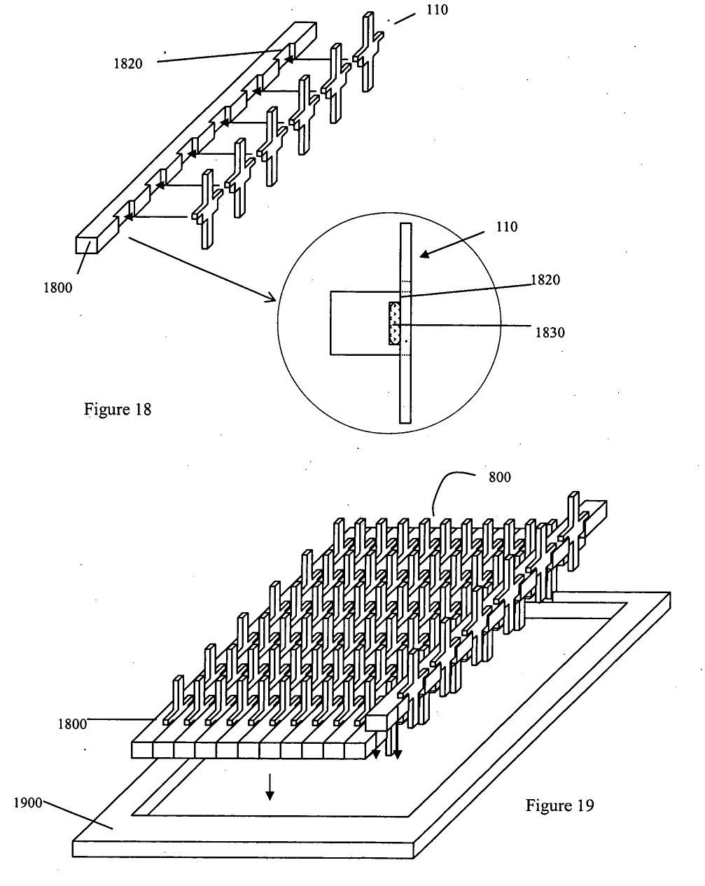

The assembled strips 1800 are then mounted together to a supporting frame 1900 to form an array 800 of laterally compliant spring elements 110, as shown in FIG. 19. An advantage of building contactor strips 1800 prior to assembly into an array 800 is that the laterally compliant spring elements 110 of the strips 1800 may be individually inspected, tested, and yielded prior to array 800 assembly. Thus, the final array assembly yield can be greatly improved.

The alignment frame 1900 and strip holders 1800 may include features designed to accurately align the strips 1800 to one another and to the frame 1900, and to fix the strips 1800 in position to the frame 1900 and to one another 1800. These features may include dowel pins and holes, slots, shoulders, threaded holes for screws, weld tabs, alignment fiducial marks, etc.

Strips 1800 of laterally compliant spring elements 110 may also be microfabricated lithographically. In such an arrangement, the laterally compliant spring elements are lithographically fabricated in batch directly to a substrate, for example, by patterned plating techniques. Then the substrate is cut into strips 1800 by dicing, Deep Reactive Ion Etching (DRIE), laser cutting, anisotropic etching, etc., and any sacrificial material is etched away to release the springs.

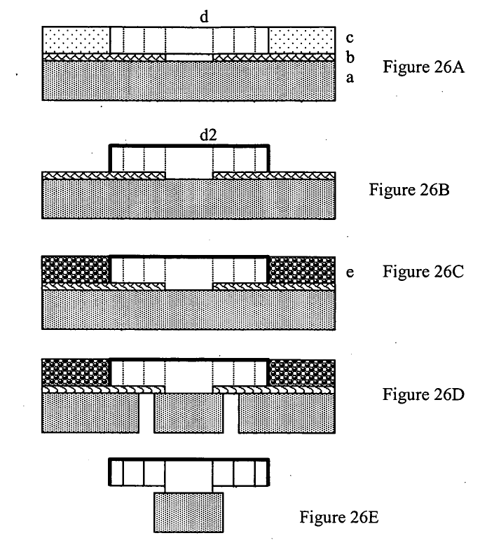

FIGS. 26A-E illustrate a method of lithographic fabrication of laterally compliant spring elements 110 on lateral contactor strips 1800. In FIGS. 26A-E, (a) is the strip substrate, (b) is the first sacrificial layer (photoresist or a sacrificial metal), (c) is the second photoresist layer, (d) is the structural layer, (d2) is the contact metal coating, (e) is the second sacrificial layer (sacrificial metal). The process sequence would be:

FIG. 26A

1. Provide a substrate with a platable seed layer on its surface.

2. Pattern a first photoresist to form a footing pattern.

3. Plate structural metal in the footing pattern.

4. Strip the photoresist and plate a first layer of sacrificial metal over the entire substrate.

5. Planarize the metals so as to expose the footing structural metal.

6. Pattern a second photoresist to form the lateral contactor spring structure.

7. Plate a second layer of structural metal in the spring pattern.

FIG. 26B

8. Strip the photoresist (dry ashing) 75% to 90% of the way down.

9. Plate a contact metal over the exposed spring structure.

10. Strip the remaining photoresist.

FIG. 26C

11. Plate a second layer of sacrificial metal thick enough to support the substrate segments through the separation process.

FIG. 26D

12. Separate the strips from one another by diamond abrasive sawing (dicing).

FIG. 26E

13. Selectively dissolve the sacrificial metal to completely free the resilient portions of the lateral spring contactors.

Such lateral contactors could also be fabricated with additional layers of structural metal (per U.S. patent application Ser. Nos. 11/019,912 and 11/102,982 incorporated herein) for added design freedom.

The strip 1800 preferably has the appropriate thermal matching characteristics as described above. The strip 1800 should also have sufficient strength and dimensional stability to maintain positional tolerances of the laterally compliant spring elements 110 when subjected to the lateral compression force and thermal environmental effects. The resulting strips 1800 of laterally compliant spring elements 110 could be pre-fabricated in standard pitches and lengths and assembled to a frame 1900 as needed. The supporting frame 1900 may be ceramic, metal, glass, or plastic, as required by its particular application. A preferred frame 1900 may be an Electric Discharge Machining (EDM) formed metal that is thermally matched to the strips 1800.

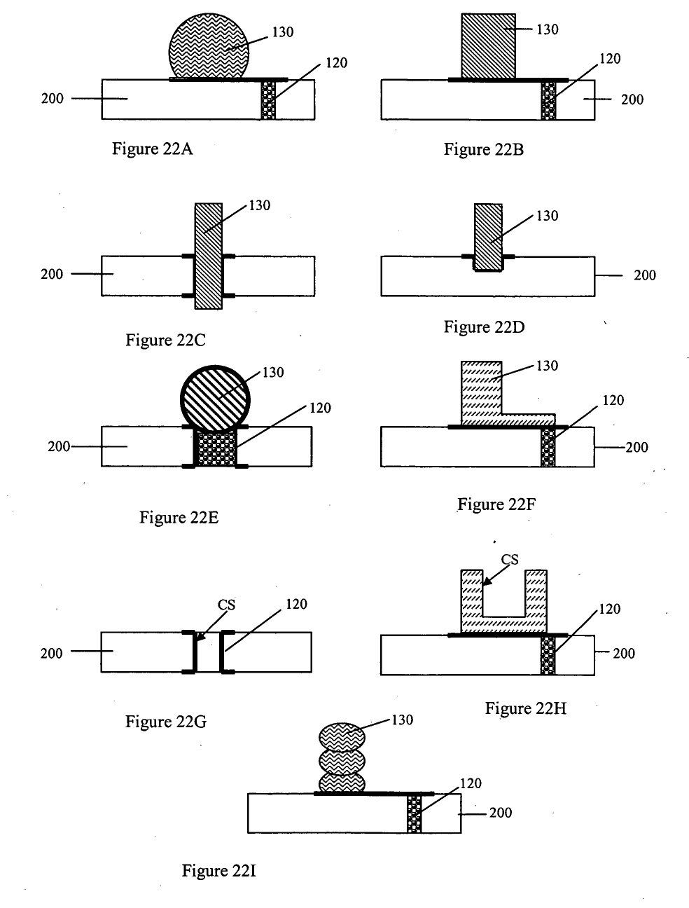

The contact bumps which are engaged by the contact regions 140A, 140B may be one of many configurations. Various possible configurations for the contact bumps 130 are shown in FIGS. 22A-22I. Some take the form of bumps or studs, while others provide more complex shapes in the form of protrusions with or without cavities, or holes. FIG. 22A depicts a contact bump 130 constructed as a solder ball on a substrate 200 (while lower substrate 200 is utilized in these figures, upper substrate 300 may also be used, as may any substrate which requires a contact bump to connect to a resilient contact element 110). FIG. 22B depicts a contact bump 130 constructed as a metal stud on a substrate 200. FIG. 22C depicts a contact bump 130 as a metal pin passing through a via 120. FIG. 22D depicts a contact bump 130 as a metal pin in a blind via. FIG. 22E depicts a contact bump 130 as a metal ball welded on to the via 120. FIG. 22F depicts a microfabricated stud on a substrate 200. FIG. 22G shows that, in some cases the contact bump 130, may not be a structure on top of the substrate 200, but rather may be a through-hole or blind hole with a conductive side wall. In FIG. 22G, the arrow marked “CS” depicts the location where the contact regions 140A, 140B may contact the “bump” 130. FIG. 22H depicts the contact bump 130 as a microfabricated cup on a substrate 200. Similar to FIG. 22G, the contact surface where the contact regions 140A, 140B will contact the “bump” 130 is indicated by the arrow “CS.” FIG. 22I shows a contact region 130 constructed as a stack of ball bumps as is know in the art of thermosonic ball bumping.

All of the configurations in FIGS. 22A-22I are generically termed “bumps” for ease of reference, even though they may be either external structures or internal structures such as a hole with a side wall. The bumps 130 may be applied to conductive areas such as traces or terminals on the substrates 200 or directly to vias 120 by various techniques including solder reflow, thermocompression bonding, thermosonic bonding, ultrasonic bonding, conductive adhesive bonding, laser welding, resistance welding, brazing, or they may be directly microfabricated on the substrate 200 by lithographic electroforming. The bumps 130 may be made of a base metal, and they may be overcoated with another metal optimized for contact properties. For example, the base metal may be Ni and the overcoated metal may be Au. Alternatively, the bumps 130 may be directly formed from a suitable contact metal such as Au or AuPd. In all cases the bumps 130 provide a structure with a surface suitable for making lateral electrical contact. The bumps 130 are configured to accept the lateral forces encountered once the lateral resilient spring element 110 is in contact with them without significant mechanical deformation, deflection, or distortion. In a preferred embodiment, the contact bump 130 is a stacked Au alloy ball bump produced by thermosonic wire bonding techniques.

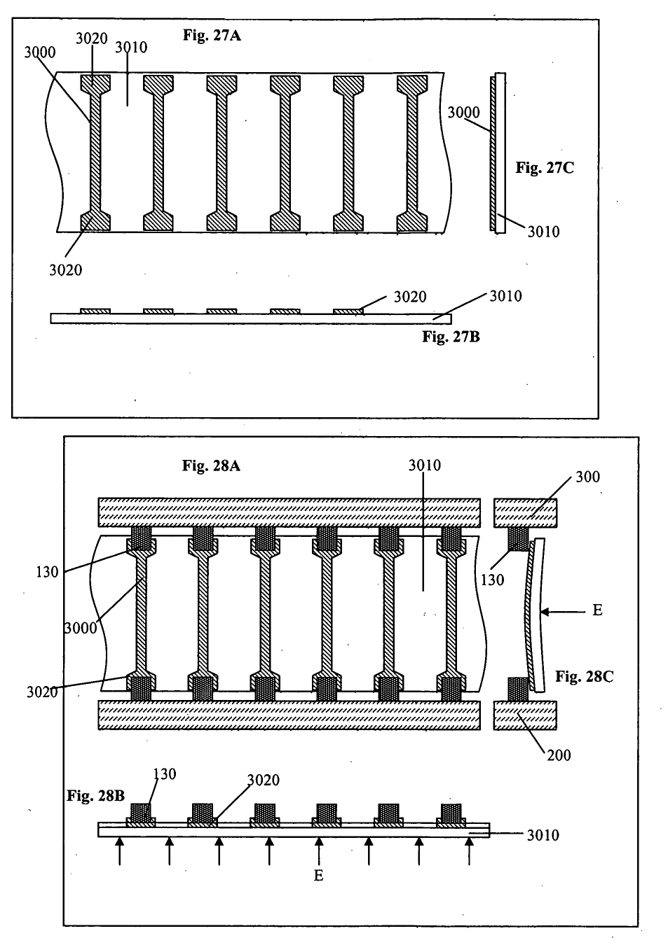

In an alternative embodiment of the present invention, the laterally compliant interposer may consist of conductive traces on a flexible wiring board (also commonly called flex-circuit technology, flexible substrate, or simply “flex”). FIG. 27A-C shows a laterally compliant interposer element according to this embodiment. FIG. 27A is a front view of the laterally compliant interposer having conductive traces 3000 which are plated, etched, or laminated onto or into a flexible substrate 3010. Most vendors who make flex commonly use a “subtractive process” which involves etching away a laminated copper layer, or an “additive process” where a very thin seed layer of copper is laminated or deposited on the plastic and the conductive strips are electroplated on top. These conductive traces 3000 have contact areas 3020 at both ends which contact the contact bumps 130. FIGS. 27B and 27C show an embodiment of the laterally compliant interposer using a flexible substrate, in an unengaged state, from the top-down and side views respectively.

Flex circuits provide a convenient technology platform which is well suited to producing electrical interconnects with excellent design freedom, shielding and impedance control characteristics. Such flex circuits are available in various configurations such as single metal layer, double metal layer, double metal layer with vias, and multi-layer. The conductive traces 3000 are most typically copper though other metals such as gold silver, palladium, platinum, nickel, and other conductive metals may be used, particularly in “build-up” or “additive” process technologies where the metal is electroformed rather than etched. It is also possible to apply a high quality spring metal on the trace to improve the mechanical spring performance. Such a metal could be from the group: Ni, NiMn, NiCu, CuZn, or NiCo. The spring metal could be plated directly on a conventional laminated flex conductor such as copper, thus forming a multi-layer conductive trace. Other resilient materials such as polymers and composites which impart a spring-like property may also be used. The base material of the flexible substrate 3010 is typically polyimide (Kapton™) or similar plastics, although other base films are available with different mechanical and electrical properties (such as Teflon™ or liquid crystal polymer or fiber reinforced resins). For the purpose of this embodiment, a base substrate film should be dimensionally stable, springable (meaning that it should have good spring resiliency characteristics with minimal creep, thermal set, and mechanical hysteresis) and have desirable electrical characteristics including stable dielectric constant and stable low loss tangent at high frequencies. Polyimide is such a suitable material and possesses exceptional spring characteristics in the class of polymer materials. A common supplier of flex circuit technology is the Sheldahl Corporation of Northfield, Minn. A typical flex substrate may have a height of 1 mm to 10 mm and a thickness of 10 um to 75 um. In certain preferred embodiments, the flex substrate may have a height of less than 5 mm and is more preferably between 2 mm and 4 mm. The flexibility of the flex is a function of both the height and the thickness, and the material properties of the base substrate and the metal layers, as well as the shape of any cutout or paddle areas (as described below). Additional springable support elements may be added to the structure as well. The conductive traces generally are between 10 um and 100 um wide, but may vary depending on the thickness of the flex. In certain preferred embodiments, the widths may be about 25 μm, 50 μm, or 100 μm with a margin of approximation being +/−20%. The contact areas generally have widths between 50 um and 500 um wide. Conventional technology allows for the distance between contact areas (the pitch) to be as small as 50 μm, but is more typically 500 μm to 1 mm. However, advances in lithographic techniques may be used to create pitches as small as 5 μm to 10 μm. The contact areas 3020 may be tailored so as to mate effectively to the bumps 130 which they are contacting and the same design elements that were described above regarding the previous embodiment may be utilized. Additionally, another possible configuration is for the conductive trace 3000 to extend beyond the flexible substrate 3010 to create a “tail,” as is illustrated in FIGS. 36 A-B. Such a tail may be only metal (for example the conductive copper overcoated with Au) or may be metal with polyimide backing. The tail configuration is particularly well suited for engagement directly into Printed Circuit Boards via holes.

FIGS. 28A-C illustrate a laterally compliant interposer utilizing a flexible substrate 3010 in an engaged state. In the engaged state, the contact areas 3020 are in contact with the contact bumps 130. FIG. 28C is a side view of the laterally compliant interposer being urged by an engagement force (denoted by the arrow referenced as “E”), such that the top and bottom contact areas 3020 are placed in contact with the contact bumps 130 on the top 300 and bottom 200 substrates respectively. When the flexible substrate 3010 and contact areas 3020 are urged against the contact bumps 130, the entire flexible substrate flexes in response to the aggregate force exerted by the row of bumps. Any variance in a particular bump's position from an ideal straight line of bumps results in a warble or local mechanical response in the flex.

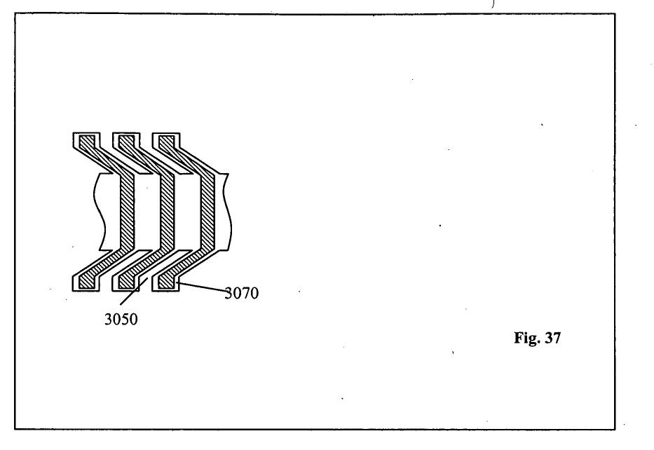

Another embodiment of the present invention utilizes cutouts on the flexible substrate to form a flexible paddle to provide even further bump-to-bump compliance (the ability to absorb bump position variance). FIG. 29A-B show the engagement of such an embodiment. FIG. 29A shows a front view of a flexible substrate 3010 which has multiple cutouts 3050 running longitudinally to create flexible paddles 3070. FIG. 29A also shows a staggered bump 3060 which is in between, but out of line of, the inline bumps 3062. FIG. 29B shows a side view of FIG. 29A. In this figure, the staggered bump 3060 is depicted as being moved to the right of the in-line bumps 3062. The design of the flexible paddles accommodates for this variance as the flexible paddle 3082 intended to engage the in-line bump 3062 is able to do so while the flexible paddle 3080 is also able to engage the staggered bump 3060. This flexible paddle design may be thought of as cantilever spring because the paddles will resume an in-line shape once the engagement force is retracted. If desired, the paddles may be designed to permanently deflect by cutting away the polyimide behind the contact area 3020 and the conductive trace 3000 that is within the paddle area. It is also possible to create springy paddle protrusions that are of other shapes by changing the shape of the cutouts 3050. For instance, serpentine paddles, created by incorporating both vertical and lateral cutouts, may add overall compliance effects as well as modify the contact's wiping motion, as can be seen in FIG. 37. Electrical contact between the contact areas 3020 and the bumps 140 can be optimized by adding non-oxidizing or conductive oxide materials to the contact area 3020 surface or to the entire conductive trace 3000 (such as Au, Ag, Rh, Ru, Pt, Pd, or contact alloys such as PdCo, etc.) This conductive coating is particularly important when a springy metal such a NiMn is used as part of the conductive trace. Additionally, microstructured materials may be applied such as conductive abrasive particle coatings (for example, diamond particle impregnated Au). All of the above coatings may be electroplated onto the trace 3000 and contact area 3020 which are disposed on the surface of the flexible substrate 3010.

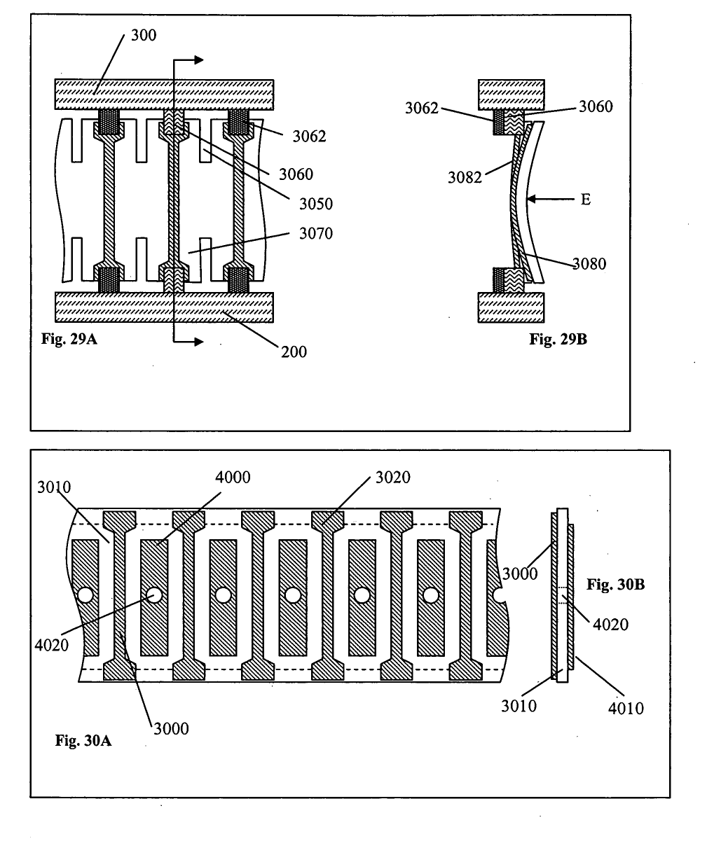

So far, the drawings have only displayed a simple conductor pattern without any special attention given to high frequency signal integrity considerations. However, the same materials and processes may be employed to form co-planar waveguides and/or multi-level stripline or microstrip waveguides. These advanced planar waveguide configurations provide unparalleled control over line impedance and cross-talk, both of which are critical parameters in high-speed test applications such as DRAM, microprocessor and system-on-chip test. FIGS. 30A-B illustrate a grounded coplanar waveguide. In addition to the conductive traces 3000, the flexible substrate 3010 also has a plurality of grounding strips 4000 in between the conductive traces. The grounding strips 4000 have vias 4020 which connect the grounding strips to a grounding plane 4010 (see FIG. 30B) which is located on the back of the flexible substrate 3010. Such a grounding strip 4000 prevents crosstalk between the conductive traces 3010 by providing a ground path for laterally radiated electromagnetic energy. The grounding strips 4000 also contribute to impedance control capability.

FIGS. 31A-B illustrates a multi-level fully shielded planar waveguide (G-S-G on the middle plane with ground planes on top and bottom). The multilevel waveguide is similar in construction to the co-planar stripline except that it has another insulating polymer layer 3010 on the front of the conductive traces 3000 and another ground plane 4010 on top of that second insulating layer. The ground planes are connected by vias 4025, or alternatively they may be connected by the holder 5000 or at a special bump location, thus providing a ground path. Dual ground planes provide more complete shielding and thus better crosstalk performance. It also isolates the traces 3000 from the holder 5000 which is an advantage if the holder is constructed from metal.

If multiple layers of metallization are employed in a flexible lateral interposer's construction, further additional signal wiring and interconnection can be accommodated within the strip itself (i.e., with more layers, the conductive traces do not need to be 1 to 1 connections from the PCB to the probe contactor substrate, rather a single point on the PCB can be fanned out to multiple points on the probe contactor substrate). For example, a common voltage could be distributed to multiple contact areas from a single source. Such a signal distribution could be accommodated using a construction employing only one metal layer (in this case only adjacent contacts can be connected), and two metal layers with vias (in which case more complex networks can be formed with or without shielding, and more than two metal layers. Components can be added to such wiring networks as noted below.

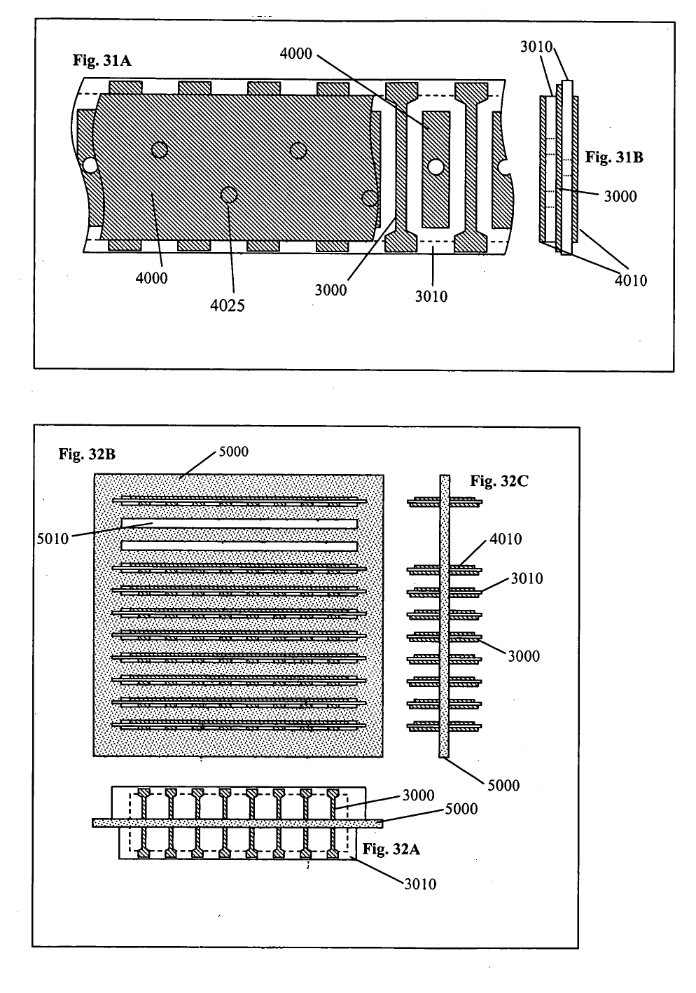

Individual flexible lateral interposers may be assembled into a 2-D array in order to form a complete lateral interposer contactor assembly as shown in FIGS. 32A-C. The individual flexible lateral interposers (including the flex substrate 3010, the conductive traces 3000, and any ground planes 4010 or grounding strips 4000) are assembled into a holder 5000 which supports the strips near their middle along their long axis. Such a holder may be a thin metal plate with machined slots 5010. The holder 5000 may also be made from a laser machined ceramic or molded plastic or any other suitable material with sufficient machinability, mechanical properties and electrical properties. If the holder 5000 is conductive, it may be grounded so as to form a shield.

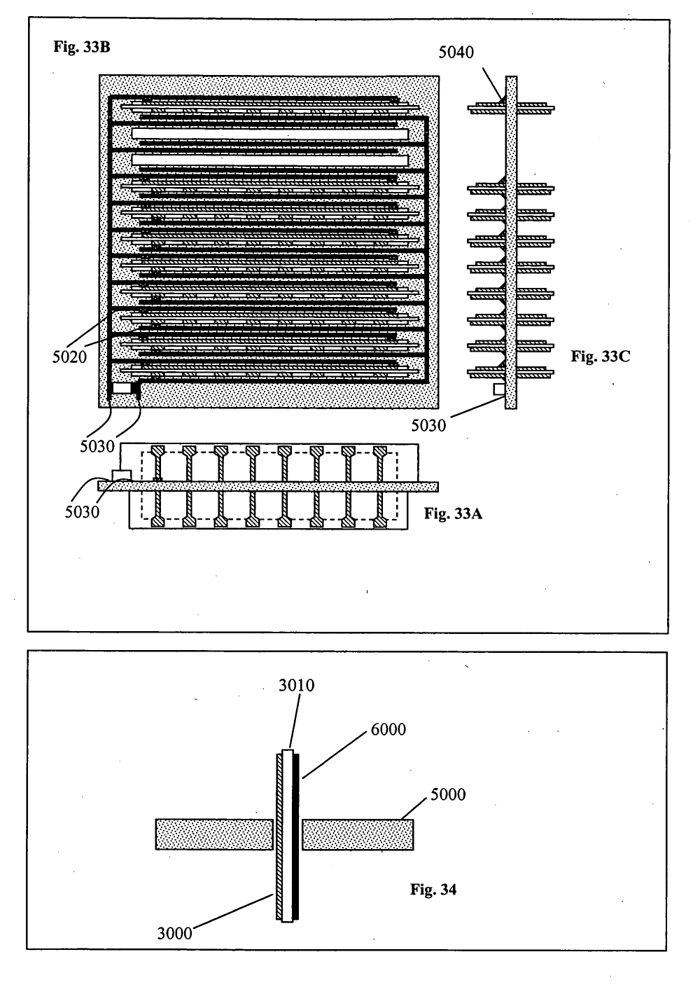

The holder 5000 may also incorporate additional wiring (distribution wiring) 5020 on the surface of the holder 5000 for the distribution of common or shared power and signals, as shown in FIGS. 33A-C. Such wiring may be of a single or multi-layer construction and may be formed directly on either or both surfaces of the holder 5000 (for example, by screen printing, thin film metallization or other methods well known in the art), or by adding an additional substrate(s) to the surface(s) of the holder 5000. These additional substrate(s) may be another flex substrate or other wiring board with slots in it to allow the flexible lateral interposers to extend through them. The advantage of using an additional wiring substrate attached to the holder 5000 is that this method allows for the decoupling of mechanical requirements and wiring requirements (the mechanical function is performed by the holder 5000, while the wiring is handled by the wiring substrate). Interconnects 5040 may be formed between the flexible lateral interposers and the distribution wiring by soldering, wire bonding, spring contact, or Tab bonding flying leads built into the flexible lateral interposer to corresponding nodes on the holder 5000 or distribution substrate. Such interconnects to the flexible lateral interposer provide a means of accessing the distribution wiring from the connections to the interposers. For example, in a probe card, a few pins at the end of the array may be dedicated to the provision of power supply and timing signals to the distribution wiring from which said signals and supplies may be connected to additional contacts.

The distribution wiring 5020 may be connected to other elements of the probe card or system components by using discrete “off-board” wiring 5030 which may be directly attached to the distribution wiring. Such “off-board” wiring may be in the form of individual wires, wire bundles, coaxial cables, shielded cables or flex circuits, all of which would extend laterally from the holder 5000. Alternatively, auxiliary spring pins may be used to extend vertically from the distribution wiring to either the PCB or the probe contactor substrate. Electronic components (including passive components such as capacitors and resistors, as well as active components such as transistors, semiconductors, integrated circuits, electro-optical devices, etc.) may be attached to the holder 5000 or wiring substrate to form a more complex network. Other features may also be designed into the interposer strips or the carrier plate so as to provide accurate registration of the various components to one another. These features can include shoulders, notches, and guide pin holes among other commonly used methods. The interposer strips may be attached to the holder 5000 by any convenient means including mechanical clips, solder, or adhesives.

In cases where the flexible interposers do not provide sufficient spring force (for example, very tall strips may not be stiff enough with practical limits on the polyimide thickness) or spring stability (for example, in high temperature applications where the polyimide or the metallic conductive traces could creep or set under load eventually losing spring force in the deflected state), a spring backing 6000 may be applied to support the strip. Such a backing 6000 takes a shape similar to the paddles 3070 or may be shaped like the conductive traces 3000 and is either bonded or electroplated on the back of the strip or simply placed behind strip in the interposer assembly. In the case of bonded or assembled backing 6000, the backing is made of a suitable spring material such as stainless steel, beryllium copper, phosphor bronze, etc. If the backing 6000 is electroplated, it may be made of NiCo, NiMn, Hard Ni, or other electroplatable spring material and may be plated directly on a backing ground plane if such a plane is incorporated. In either case, the backing material is chosen (in terms of material properties and dimensions) so as to dominate the combined spring in terms of stiffness so that the non-ideal spring behavior of the flexible interposer is small in comparison the backing 6000 spring. Such backing 6000 may be electrically isolated from the flexible interposer or distribution wiring 5020 or may be electrically attached to the network and can thus act as a shield or signal path. Although FIG. 34 illustrates the backing 6000 in a simple single layer flexible interposer, the backing can be used with multi-level flexible interposers. It may be more desirable in the latter configuration because the additional metal used in a multi-layered configuration can compromise the spring behavior of the flexible interposer without addition backing 6000.

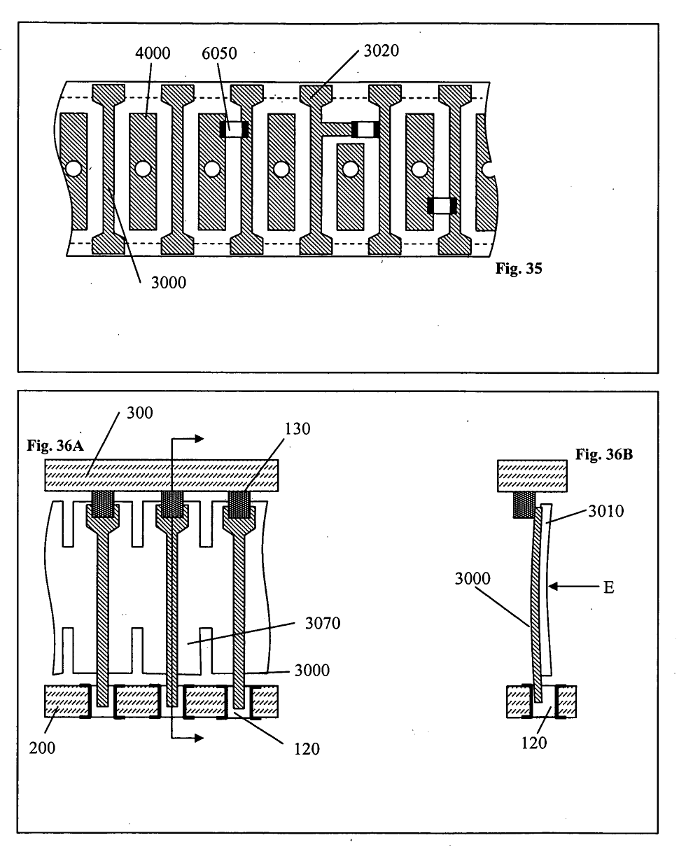

A variety of electrical components 6050 may be attached to the flexible interposers, as shown in FIG. 35. Such components may include power supply bypass capacitors, power regulators, signal or supply switching transistors, integrated circuits such as multiplexers, power regulators, and signal conditioners among many others. The components 6050 may be attached to some or all of the flexible interposers as needed. The components 6050 may be attached by conventional soldering, conductive adhesive, die attach and wire bond, flip-chip, or other ways commonly known in the art. The components 6050 can be used to form electronic networks on the flexible interposer, further integrating electrical functionality into the interposer. This integration of electronics in the interposer allows for greater design flexibility as well as a reduction in complexity of the other components in a probe card.

While particular elements, embodiments, and applications of the present invention have been shown and described, it is understood that the invention is not limited thereto since modifications may be made by those skilled in the art, particularly in light of the foregoing teaching. It is therefore contemplated by the appended claims to cover such modifications and incorporate those features which come within the spirit and scope of the invention.

What is claimed is:

1. An interposer comprising:
a flexible wiring board; and
at least one electrically conductive trace disposed on one side of the flexible wiring board, wherein the at least one conductive trace has an upper contact area adapted to contact a side wall of a first contact bump and a lower contact area adapted to contact a side wall of a second contact bump.

2. The interposer of claim 1 wherein the conductive trace comprises copper, gold, silver, palladium, platinum, or nickel.

3. The interposer of claim 1, wherein the conductive trace is resilient.

4. The interposer of claim 3, wherein the conductive trace comprises Ni, NiMn, NiCu, CuZn, or NiCo.

5. The interposer of claim 1, wherein the flexible wiring board is less than 5 mm in height.

6. The interposer of claim 1, wherein the conductive trace is about 50 μm wide.

7. The interposer of claim 1, wherein the lower contact area extends beyond the flexible wiring board to form a tail that is adapted to contact a via.

8. The interposer of claim 1, wherein the flexible wiring board includes cutouts to form flexible paddles around the contact areas.

9. The interposer of claim 8, wherein the flexible paddle is serpentine in shape.

10. The interposer of claim 1 wherein a non-oxidizing material or a conductive oxide material is further applied to the lower contact area.

11. The interposer of claim 1, further including a grounding strip applied to the same side of the flexible wiring substrate on which the conductive trace is disposed, said grounding strip being electrically connected to a first grounding plane, the first grounding plane being applied to the opposite side of the flexible wiring board.

12. The interposer of claim 11, further including an insulating polymer layer overlaying the conductive trace and the grounding strip, and a second grounding plane overlaying the insulating polymer layer, said second grounding plane being electrically connected to the first grounding plane.

13. A probe card assembly comprising:
an upper substrate having a lower surface, the lower surface having at least one upper contact bump;
a lower substrate having an upper surface, the upper surface having at least one lower contact bump; and
a flexible wiring board being disposed vertically between the upper substrate and the lower substrate, the flexible wiring board having at least one electrically conductive trace disposed on one side of the flexible wiring board, the at least one conductive trace having an upper contact area contacting a side wall of the upper contact bump and a lower contact area contacting a side wall of the lower contact bump.

14. The probe card assembly of claim 13, wherein the conductive trace is resilient.

15. The probe card assembly of claim 14, wherein the conductive trace comprises Ni, NiMn, NiCu, CuZn, or NiCo.

16. The probe card assembly of claim 13, wherein the flexible wiring board is less than 5 mm in height.

17. The probe card assembly of claim 13, wherein the conductive trace is about 50 μm wide.

18. The probe card assembly of claim 13, wherein the flexible wiring board includes cutouts to form a flexible paddle around the lower contact area.

19. The probe card assembly of claim 18, wherein the flexible paddle is serpentine in shape.

20. The probe card assembly of claim 13 wherein a non-oxidizing material or a conductive oxide material is further applied to the lower contact area.

21. The probe card assembly of claim 13, further including a grounding strip applied to the same side of the flexible wiring substrate on which the conductive trace is disposed, said grounding strip being electrically connected to a first grounding plane, the first grounding plane being applied to the opposite side of the flexible wiring board.

22. The probe card assembly of claim 11, further including an insulating polymer layer overlaying the conductive trace and the grounding strip, and a second grounding plane overlaying the insulating polymer layer, said second grounding plane being electrically connected to the first grounding plane.

23. A method of using a flexible substrate as an interposer between an upper contact bump and a lower contact bump comprising:
providing a flexible substrate having at least one electrically conductive trace on a first side of the flexible substrate, said electrically conductive trace having an upper contact area and a lower contact area;
providing an upper substrate having an upper contact bump, said upper contact bump having a top, a bottom, and at least a side extending between the top and the bottom;
providing a bottom substrate having a bottom contact bump, said bottom contact bump having a top, a bottom, and at least one side extending between the top and the bottom; and
urging the flexible substrate towards both the upper contact bump and the lower contact bump such that the upper contact area contacts the side of the upper contact bump and the lower contact area contacts the side of the lower contact bump.

24. The method of claim 23, wherein the conductive trace is resilient.

25. The method of claim 24, wherein the conductive trace comprises Ni, NiMn, NiCu, CuZn, or NiCo.

26. The method of claim 23, wherein the flexible wiring board is less than 5 mm in height.

27. The method of claim 23, wherein the conductive trace is about 50 μm wide.

28. The method of claim 23, wherein the flexible wiring board includes cutouts to form a flexible paddle around the lower contact area.

29. The method of claim 28, wherein the flexible paddle is serpentine in shape.

30. The method of claim 23 wherein a non-oxidizing material or a conductive oxide material is further applied to the lower contact area.

31. The method of claim 23, further including a grounding strip applied to the first side of the flexible wiring substrate, said grounding strip being electrically connected to a first grounding plane, the first grounding plane being applied to the side opposite of the first side of the flexible wiring board.

32. The method of claim 31, further including an insulating polymer layer overlaying the conductive trace and the grounding strip, and a second grounding plane overlaying the insulating polymer layer, said second grounding plane being electrically connected to the first grounding plane.

33. A lateral interposer for providing an electrical signal pathway between two contact elements, comprising a flexible wiring board having a conductive trace disposed on one side of the flexible wiring board urged towards an upper contact element and a lower contact element and an upper contact area of the conductive trace contacting a side wall of the upper contact element, and a lower contact area of the conductive trace contacting a side wall of the lower contact element to complete an electrical path between the upper contact element and the lower contact element.

34. The interposer of claim 1, further including a springable metal applied to a second side of the flexible wiring board, the second side being the side opposite of the flexible wiring board on which the conductive trace is disposed.

35. The interposer of claim 7, wherein the tail is overcoated with another metal.

36. The probe card assembly of claim 13, wherein the flexible wiring board is about 2 mm to 4 mm in height.

37. The probe card assembly of claim 13, wherein the flexible wiring board is about 2 mm in height.

38. The probe card assembly of claim 13, wherein the flexible wiring board is about 4 mm in height.

39. The probe card assembly of claim 13, wherein the conductive trace is about 25 μm wide.

40. The probe card assembly of claim 13, wherein the conductive trace is about 100 μm wide.

41. The probe card assembly of claim 1, wherein the flexible wiring board is about 2 mm to 4 mm in height.

42. The probe card assembly of claim 1, wherein the flexible wiring board is about 2 mm in height.

43. The probe card assembly of claim 1, wherein the flexible wiring board is about 4 mm in height.

44. The probe card assembly of claim 1, wherein the conductive trace is about 25 μm wide.

45. The probe card assembly of claim 1, wherein the conductive trace is about 100 μm wide.

46. The probe card assembly of claim 23, wherein the flexible wiring board is about 2 mm to 4 mm in height.

47. The probe card assembly of claim 23, wherein the flexible wiring board is about 2 mm in height.

48. The probe card assembly of claim 23, wherein the flexible wiring board is about 4 mm in height.

49. The probe card assembly of claim 23, wherein the conductive trace is about 25 μm wide.

50. The probe card assembly of claim 23, wherein the conductive trace is about 100 μm wide.
